(19) United States
(12) Patent Application Publication
(10) Pub. No.: US 2021/0233822 A1
(43) Pub. Date: Jul. 29, 2021

(54) SEMICONDUCTOR DEVICE, PAD STRUCTURE AND FABRICATION METHOD THEREOF

(71) Applicant: Changxin Memory Technologies, Inc., Hefei (CN)

(72) Inventor: Chih-Wei CHANG, Hefei (CN)

(21) Appl. No.: 17/231,906

(22) Filed: Apr. 15, 2021

Related U.S. Application Data
(63) Continuation of application No. PCT/CN2019/117394, filed on Nov. 12, 2019.

(30) Foreign Application Priority Data
Nov. 12, 2018 (CN) 201811341175.3
Nov. 12, 2018 (CN) 201821858974.3

(51) Int. Cl. H01L 21/66; H01L 23/00

(52) U.S. Cl. CPC H01L 22/32; H01L 2224/04042; H01L 24/05; H01L 24/03; H01L 2224/06515; H01L 2224/06102; H01L 2224/05008; H01L 2224/05009; H01L 2224/02233; H01L 2224/0312; H01L 2224/0311; H01L 2224/03622; H01L 2224/03831; H01L 2224/05647; H01L 2224/05624; H01L 2224/05684; H01L 2224/05666; H01L 2224/05644; H01L 2224/05639; H01L 24/06

(57) ABSTRACT

A semiconductor device, a pad structure, and fabricating methods thereof are provided, relating to the field of semiconductor technology. The pad structure includes a substrate, a first dielectric layer, a groove, a bonding pad and a test pad. The first dielectric layer is disposed on the substrate, and the groove is disposed in the first dielectric layer. One of the bonding pad and the test pad is disposed outside the groove and on the surface of the first dielectric layer not adjacent to the substrate, and the other one is disposed on a bottom of the groove. The semiconductor device, the pad structure, and related fabricating methods improve the production yield and stability of the semiconductor device.

### CROSS-REFERENCE TO RELATED APPLICATIONS

This application is a continuation application of International Patent Application No. PCT/CN2019/117394, filed on Nov. 12, 2019, which is based on and claims priority of the Chinese Patent Applications No. 201811341175.3 and No. 201821858974.3, both filed on Nov. 12, 2018. The above-referenced applications are incorporated herein by reference in their entirety.

### TECHNICAL FIELD

This present invention relates generally to the field of semiconductor technologies and more specifically, but not by way of limitation, to a semiconductor device, a pad structure, and a fabrication method thereof.

### BACKGROUND

With the development of semiconductor technology, semiconductor devices are increasingly ubiquitously deployed in residential and industrial applications. Semiconductor devices, such as chips, may connect to external devices via pads. However, the pad and the external connection lines are susceptible to disruptions, which may lead to unreliable connections and lower the production yield and stability of the semiconductor device.

The above information disclosed in this Background section is only used to facilitate the understanding of the background of the present invention, and thus it may include information that does not constitute the prior art known to those of ordinary skills in the art.

### SUMMARY

In view of the limitations of existing technologies described above, the present invention provides a semiconductor device, a pad structure, and related fabrication methods that address the aforementioned limitations, including unstable connection between the pad and external devices.

One aspect of the present invention is directed to a pad structure. The pad structure may include: a substrate; a first dielectric layer disposed on the substrate; a groove disposed in the first dielectric layer; a bonding pad and a test pad. One of the bonding pad and the test pad may be disposed outside the groove and on the surface of the first dielectric layer not adjacent to the substrate, and the other one of the bonding pad and the test pad may be disposed on a bottom of the groove.

In some embodiments of the present invention, the bonding pad may be disposed outside the groove and on the surface of the first dielectric layer not adjacent to the substrate, and the test pad may be disposed on the bottom of the groove.

In some embodiments of the present invention, the groove may have a depth in a range of 100 nm to 1 μm.

In some embodiments of the present invention, the substrate may include a wiring layer. The wiring layer may include a test wiring connected to the test pad.

In some embodiments of the present invention, the test wiring may be exposed by the groove, and the test pad may be coupled to an exposed surface of the test wiring.

In some embodiments of the present invention, the wiring layer may further include a solder wiring coupled to the bonding pad.

In some embodiments of the present invention, the solder wiring may be coupled to the bonding pad via a conductive pillar passing through the first dielectric layer.

In some embodiments of the present invention, the test pad and the bonding pad may be isolated from each other.

In some embodiments of the present invention, the test pad and the bonding pad may be coupled to each other via a conductive connection structure.

In some embodiments of the present invention, a distance between a surface of the test pad facing away from the substrate and the substrate may be 100 nm to 1 μm shorter than a distance between a surface of the bonding pad facing away from the substrate and the substrate.

In some embodiments of the present invention, the test pad and the bonding pad may be made of a same material.

In some embodiments of the present invention, the test pad may have a thickness same as a thickness of the bonding pad.

In some embodiments of the present invention, the pad structure may further include a protective layer disposed on a side of the first dielectric layer not adjacent to the substrate and exposing the test pad and the bonding pad.

Another aspect of the present invention is directed to a method of fabricating a pad structure. The method may include: providing a substrate; forming a first dielectric layer on the substrate; forming a groove in the first dielectric layer; and forming a bonding pad and a test pad. One of the bonding pad and the test pad may be disposed outside the groove and on a surface of the first dielectric layer not adjacent to the substrate, and the other one of the bonding pad and the test pad may be disposed on a bottom of the groove.

In some embodiments of the present invention, forming the groove in the first dielectric layer may include: forming a photoresist layer on the surface of the first dielectric layer not adjacent to the substrate; exposing the photoresist layer with respect to a mask to transfer a pattern of the mask to the photoresist layer; developing the photoresist layer to expose a groove area for forming the groove; etching the groove area to form the groove; and removing the photoresist layer.

In some embodiments of the present invention, forming the bonding pad and the test pad may include: forming a conductive film layer covering the bottom of the groove and the surface of the first dielectric layer not adjacent to the substrate; forming a photoresist protection layer on a surface of the conductive film layer facing away from the substrate, with the photoresist protection layer having a pattern of the bonding pad and the test pad exposing a portion of the conductive film layer; removing the exposed portion of the conductive film layer by etching; and removing the photoresist protective layer.

In some embodiments of the present invention, forming a photoresist protective layer on the surface of the conductive film layer facing away from the substrate may include: forming a photoresist layer on the surface of the conductive film layer facing away from the substrate; exposing the photoresist layer with respect to a mask to transfer a pattern of the mask to the photoresist layer; and developing the photoresist layer so that the photoresist layer only covers areas where the bonding pad and the test pad are to be formed.

In some embodiments of the present invention, the bonding pad and the test pad may be coupled to each other via a conductive connection structure, and forming a photoresist protection layer on a surface of the conductive film layer facing away from the substrate may include: forming a photoresist layer on the surface of the conductive film layer facing away from the substrate; exposing the photoresist layer with respect to a mask to transfer a pattern of the mask to the photoresist layer; and developing the photoresist layer so that the photoresist layer only covers areas where the bonding pad, the test pad, and the conductive connection structure are to be formed.

Another aspect of the present invention is directed to a semiconductor device including a pad structure. The pad structure may include: a substrate; a first dielectric layer disposed on the substrate; a groove disposed in the first dielectric layer; and a bonding pad and a test pad. One of the bonding pad and the test pad may be disposed outside the groove and on the surface of the first dielectric layer not adjacent to the substrate, and the other one of the bonding pad and the test pad may be disposed on a bottom of the groove.

In some embodiments of the present invention, the bonding pad may be disposed outside the groove and on the surface of the first dielectric layer not adjacent to the substrate, and the test pad may be disposed on the bottom of the groove.

In the semiconductor device, the pad structure and related fabrication methods of the present invention, the bonding pad and the test pad are separated from each other, therefore, even if the test pad is damaged when contacting with the test probe, the bonding pad will not be adversely affected. Thus, a reliable connection between the bonding pad and a connection line can be established, and the production yield and stability of the semiconductor device can be improved.

### BRIEF DESCRIPTION OF THE DRAWINGS

The above and other features and advantages of the present invention will become more apparent from the detailed description of the embodiments.

FIG. 1 is a schematic diagram showing a pad structure in the prior art.

FIG. 2 is a schematic diagram illustrating a pad structure in accordance with one embodiment of the present invention.

FIG. 3 is a schematic diagram illustrating a pad structure in operation in accordance with one embodiment of the present invention.

FIG. 4 is a schematic diagram illustrating a pad structure in accordance with one embodiment of the present invention.

FIG. 5 is a flowchart illustrating a method for fabricating a pad structure in accordance with one embodiment of the present invention.

FIG. 6 is a schematic diagram illustrating a region for forming a groove on a first dielectric layer in accordance with one embodiment of the present invention.

FIG. 7 is a schematic diagram illustrating a groove formed on a first dielectric layer in accordance with one embodiment of the present invention.

FIG. 8 is a flowchart illustrating a method for fabricating a test pad and a bonding pad in accordance with one embodiment of the present invention.

FIG. 9 is a schematic diagram illustrating a conductive film layer in accordance with one embodiment of the present invention.

FIG. 10 is a schematic diagram illustrating a photoresist protective layer formed on a conductive film layer in accordance with one embodiment of the present invention.

FIG. 11 is a schematic diagram illustrating a test pad and a bonding pad in accordance with one embodiment of the present invention.

FIG. 12 is a schematic diagram a photoresist protective layer formed on a conductive film layer in accordance with one embodiment of the present invention.

### DETAIL DESCRIPTION OF THE EMBODIMENTS

Example embodiments will now be described more fully with reference to the accompanying drawings. However, the example embodiments can be embodied in a variety of forms and should not be construed as being limited to the examples set forth herein. Rather, these embodiments are provided so that this present invention will be more comprehensive and complete to those skilled in the art. The described features, structures, or characteristics may be combined in any suitable manner in one or more embodiments. In the following description, numerous specific details are set forth to provide a thorough understanding of the embodiments of the present invention.

In the drawings, the thickness of the regions and layers may be exaggerated for clarity. The same reference numerals in the drawings may denote the same or similar structures, and thus their detailed description will be omitted.

When a structure is “on” another structure, it may mean that a structure is integrally formed on another structure, or that a structure is “directly” disposed on another structure, or that a structure is “indirectly” disposed on another structure. The terms “a”, “an”, and “the” are used to mean the presence of one or more elements/components. The terms “including” and “having” are used to mean an inclusive meaning and are meant to mean additional elements/components in addition to the listed elements/components may be present. The terms “first” and “second” are used as labels only, not the number of objects.

In the related art, as shown in FIG. 1, a pad 001 on the semiconductor device may often be used both as a test pad for contacting with a test probe and as a bonding pad for connection with a conductive connection line 002.

However, when the semiconductor device is tested, the test probe, by contacting the pad 001, may easily cause damage 004 (e.g., scratches or dust) to the pad 001. The damage 004 on the pad 001 may disrupt a connection between the pad 001 and the conductive connection line 002, and the conductive connection line 002 (i.e., wire bonding) may become susceptible to disengage. Thus, the production yield and stability of the semiconductor device may be reduced.

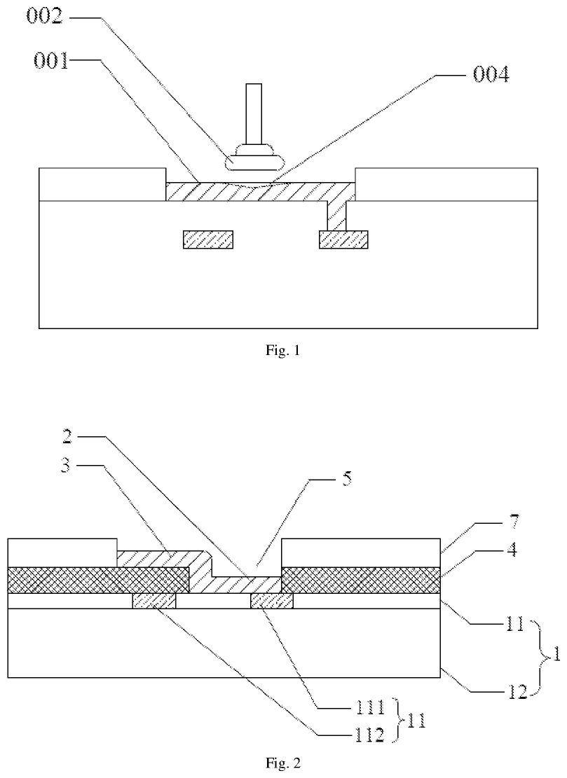

The present invention provides a pad structure. As shown in FIG. 2, the pad structure may include a substrate 1, a first dielectric layer 4, a groove 5, a bonding pad 3, and a test pad 2.

The first dielectric layer 4 may be disposed on the substrate 1, the groove 5 may be disposed on a surface of the first dielectric layer 4 not adjacent to the substrate 1. In some embodiments, the groove 5 may be disposed in the first dielectric layer 4. One of the bonding pad 3 and the test pad 2 may be disposed outside the groove and on the surface of the first dielectric layer 4 not adjacent to the substrate 1, and the other one of the bonding pad 3 and the test pad 2 may be disposed on a bottom of the groove 5.

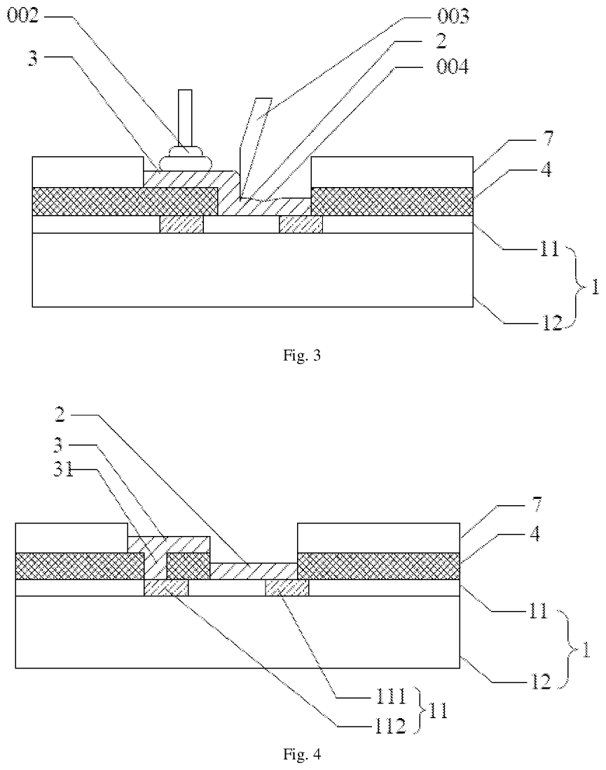

In the pad structure of the present invention, the bonding pad 3 may be connected with the conductive connection line 002, and the test pad 2 may be used to contact with a test probe 003 (shown in FIG. 3). The bonding pad 3 and the test pad 2 may be separated from each other, and therefore, even if the test pad 2 is damaged when it comes into contact with the test probe 003, the bonding pad 3 is not affected. Thus, the bonding pad 3 may establish a reliable connection with the conductive connection line 002, and the production yield and stability of the semiconductor device can be improved.

The components of the pad structure provided by the embodiments of the present invention are described in detail below with reference to the accompanying drawings.

As shown in FIG. 2, the substrate 1 may include a second dielectric layer 12 and a wiring layer 11. The wiring layer 11 may be disposed between the second dielectric layer 12 and the first dielectric layer 4.

The material of the second dielectric layer 12 may be selected and determined according to the design requirements of the semiconductor device, and may be an organic insulating material, an inorganic insulating material, or a mixed material of an organic insulating material and an inorganic insulating material. For example, in one embodiment, the material of the second dielectric layer 12 may be one or more of silicon oxide, silicon nitride, and amorphous silicon. The second dielectric layer 12 may include one single layer of insulating material or a plurality of layers of different insulating materials.

As shown in FIG. 2, the wiring layer 11 may include a test wiring 111. The test wiring 111 may be connected to the test pad 2 for testing of integrated circuits (ICs).

In one embodiment, the test wiring 111 and the test pad 2 may be separated from each other by the first dielectric layer 4, and may be connected with each other via one or more conductive pillars. When fabricating the conductive pillar, a via hole may be formed on the groove 5. The via hole may expose the test wiring 111. Then, when forming the test pad 2, the material of the test pad 2 may be filled in the via hole to form the conductive pillar. The conductive pillar can not only establish the connection between the test pad 2 and the test wiring 111, but also provide support to the test pad 2.

In one embodiment, as shown in FIG. 2, the groove 5 may expose the test wiring 111, and the test pad 2 may connect to the exposed surface of the test wiring 111. Thus, direct contact between the test pad 2 and the test wiring 111 can be established.

As shown in FIG. 4, the wiring layer 11 may further include a solder wiring 112. The solder wiring 112 may be connected to the bonding pad 3 for connecting the semiconductor device to an external device or circuit. The orthographic projection of the bonding pad 3 on the wiring layer 11 may at least partially overlap the solder wiring 112, and the bonding pad 3 and the solder wiring 112 may be connected by the conductive pillar 31 passing through the first dielectric layer 4.

The conductive pillar 31 may be formed by first forming a via hole in the first dielectric layer 4, with the via hole exposing the solder wiring 112. Then, when forming the bonding pad 3, a material of the bonding pad 3 may be filled in the via hole to form a conductive pillar 31. The conductive pillar 31 can not only establish the connection between the bonding pad 3 and the soldering wire 112, but also provide support to the bonding pad 3. When bonding or soldering the conductive connecting wire 002, the supporting force of the bonding pad 3 may be effectively improved, and the production yield of the packaged product may be improved.

The material of the first dielectric layer 4 may be selected and determined according to the design requirements of the semiconductor device, and may be an organic insulating material or an inorganic insulating material. For example, in an embodiment, the material of the first dielectric layer 4 may be one or more of silicon oxide, silicon nitride, and amorphous silicon. The first dielectric layer 4 may include one single layer of insulating material or a plurality of layers of different insulating materials.

The depth of the groove 5 may be determined according to the design requirements or structure of the semiconductor device. The groove 5 may or may not penetrate the first dielectric layer 4.

In one embodiment, the depth of the groove 5 may be in a range of 100 nm to 1 μm. Thus, the sidewalls of the groove 5 may effectively block the test probe 003. The test pad 2 and the bonding pad 3 may be connected by a conductive connection structure, which may cover a portion of the sidewall of the groove 5 between the test pad 2 and the bonding pad 3. The test pad 2 and the bonding pad 3 as a whole may have a stair-wise shape. The conductive connection structure may block the test probe 003 to prevent the test probe 003 from scratching into the bonding pad 3 during testing, thereby reducing, if not completely preventing, the damage of the bonding pad 3.

In one embodiment, as shown in FIG. 2, the bonding pad 3 may be disposed on the surface of the first dielectric layer 4 not adjacent to the substrate 1. The test pad 2 may be disposed on the bottom of the groove 5. As such, the surface of the bonding pad 3 may be farther from the substrate 1 than the test pad 2. Thus, the bonding pad 3 may protrude from the surface of the test pad 2. As shown in FIG. 3, when the test probe 003 is moved close to the edge of the groove 5, it will be blocked by the sidewall of the groove 5 or the device attached to the sidewall, so that the test probe 003's movement is restrained within the groove 5. That reduces the chance of the test probe 003 erroneously intruding into the bonding pad 3 and causing damage to the bonding pad 3 when moving on the surface of the test pad 2, and the structural integrity of the bonding pad 3 may be ensured. In one embodiment, the distance between a surface of the test pad 2 facing away from the substrate and the substrate 1 may be 100 nm to 1 μm shorter than a distance between a surface of the bonding pad 3 facing away from the substrate and the substrate 1.

In one embodiment, the bonding pad 3 may be disposed on the bottom of the groove 5, and the test pad 2 may be disposed on the surface of the first dielectric layer 4 not adjacent to the substrate 1.

The shape of the test pad 2 may be a square, rectangular, circular, elliptical, regular hexagon. The shape of the test pad 2 may be any other suitable shape that can be fabricated by a patterning process, can establish reliable contact with the test probe 003 while not adversely affecting other devices. The size (surface size and thickness) of the test pad 2 can be determined according to the design requirements of the semiconductor device to effectively accommodate the test probe 003 for a test. The shape and size of the test pad 2 are not limited in the present invention.

The material of the test pad 2 may be a conductive material and may be a metal material, a metal oxide material or other materials. The test pad 2 may include one single layer of conductive material or a plurality of layers of different conductive materials. For example, the material of the test pad 2 may be one of copper, aluminum, tungsten, titanium, gold, silver or an alloy of the above materials.

The shape, size, and material of the bonding pad 3 may be the same as or different from those of the test pad 2, which is not particularly limited in the present invention.

In one embodiment, the test pad 2 and the bonding pad 3 may be of the same material, such that the test pad 2 and the bonding pad 3 may be fabricated in a same process. In particular, if the test pad 2 and the bonding pad 3 are connected by a conductive connection structure, and the three are made of the same material, the test pad 2, the bonding pad 3 and the conductive connection structure may be fabricated at the same time.

In one embodiment, the test pad 2 and the bonding pad 3 may have the same thickness. Thus, the bonding pad 3 may protrude from the surface of the test pad 2. In particular, when the test pad 2 and the bonding pad 3 are made of a same material, both can be fabricated through the same conductive film layer, which may simplify the fabrication process of the pad structure.

As shown in FIG. 2, the pad structure may further include a protective layer 7, the protective layer 7 may be disposed on a side of the first dielectric layer 4 not adjacent to the substrate 1. The opening formed in the protective layer 7 may expose the test pad 2 and the bonding pad 3, and the upper surface of the protective layer 7 may be higher than the upper surfaces of the test pad 2 and the bonding pad 3. The protective layer 7 may include one single layer of a protective material or a plurality of layers of different protective materials. For example, the protective material can be polyimide.

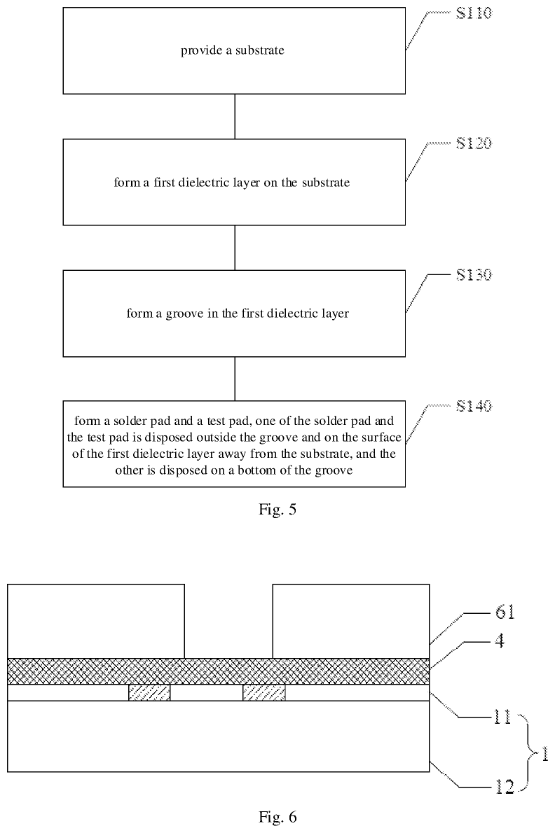

The present invention further provides a method for fabricating a pad structure. As shown in FIG. 5, the method for fabricating the pad structure may include the following steps S110 to S140.

In step S110, a substrate 1 may be provided.

In step S120, a first dielectric layer 4 may be formed on the substrate 1.

In step S130, a groove 5 may be formed in the first dielectric layer 4.

In step S140, a bonding pad 3 and a test pad 2 may be formed. One of the bonding pad 3 and the test pad 2 may be disposed outside the groove and on the surface of the first dielectric layer 4 not adjacent to the substrate 1, and the other one may be disposed on the bottom of the groove 5.

In step S120, the first dielectric layer 4 may be formed on the substrate 1 by methods such as chemical vapor deposition, atomic layer deposition.

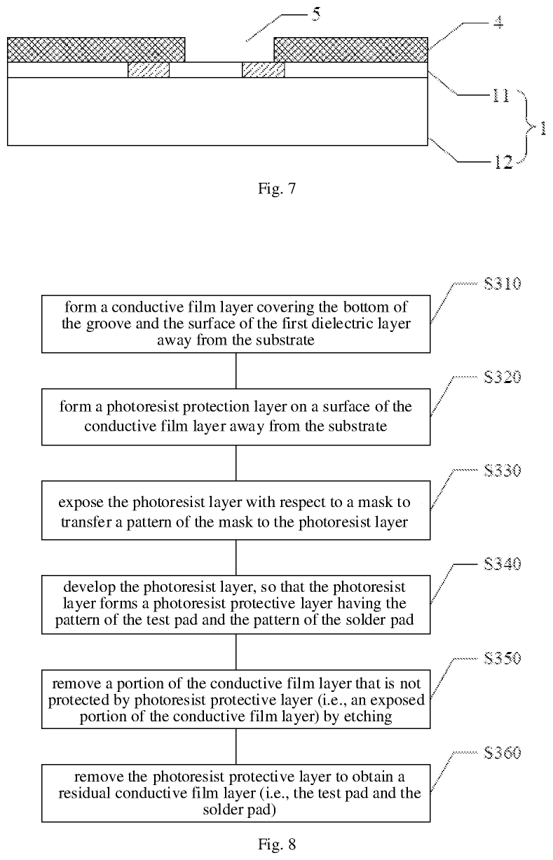

In step S130, the groove 5 may be formed by a mask process-lithography process. For example, in one embodiment, with reference to FIGS. 6 and 7, the mask process-lithography process may include the following steps S210 to S250.

In step S210, a photoresist layer 61 may be formed on the surface of the first dielectric layer 4 not adjacent to the substrate 1.

In step S220, the photoresist layer 61 may be exposed with respect to a mask to transfer a pattern of the mask to the photoresist layer 61, as shown in FIG. 6.

In step S230, the photoresist layer 61 may be developed to expose a groove area for forming a groove 5.

In step S240, the groove 5 may be formed by etching.

In step S250, the photoresist layer 61 may be removed to form the structure as shown in FIG. 7.

In one embodiment, the bonding pad 3 and the test pad 2 may have different materials or different thicknesses, and in step S140, the bonding pad 3 and the test pad 2 may be formed separately.

In one embodiment, the bonding pad 3 and the test pad 2 may have the same material and the same thickness, and the bonding pad 3 and the test pad 2 may be formed simultaneously. The bonding pad 3 and the test pad 2 can be formed by methods such as physical vapor deposition, plating, evaporation, etc. In one example, with reference to FIGS. 8, 9, 10, and 11, the bonding pad 3 and the test pad 2 may be formed through the following steps S310 to S360.

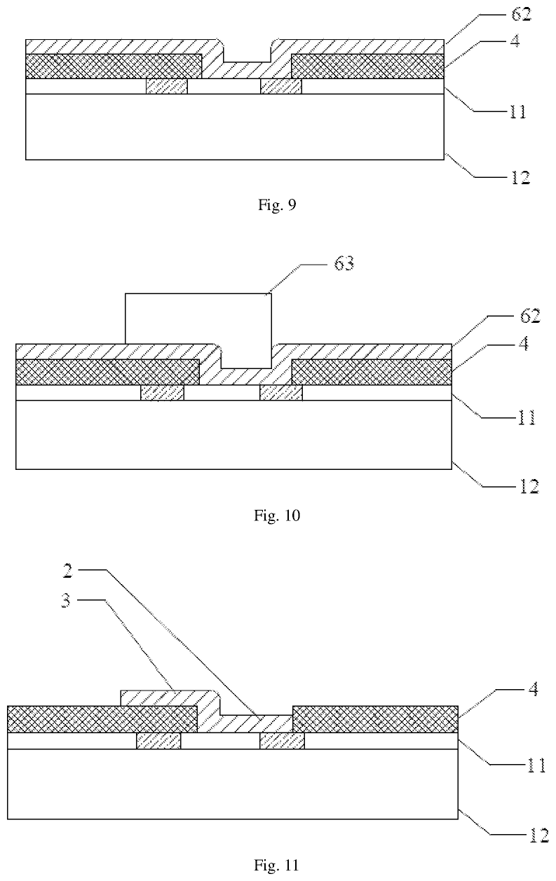

In step S310, a conductive film layer 62 covering the bottom of the groove 5 and the surface of the first dielectric layer 4 not adjacent to the substrate 1 may be formed, as shown in FIG. 9.

In step S320, a photoresist layer may be formed on the surface of the conductive film layer 62 facing away from the substrate 1.

In step S330, the photoresist layer may be exposed with respect to a mask, so that a pattern of the mask may be transferred to the photoresist layer.

In step S340, the photoresist layer may be developed to form a photoresist protective layer 63 having the pattern of the test pad 2 and the pattern of the bonding pad 3, as shown in FIG. 10.

In step S350, a portion of the conductive film layer 62 that is not protected by the photoresist protective layer 63 (i.e., an exposed portion of the conductive film layer 62) may be removed by etching.

In step S360, the photoresist protective layer 63 may be removed to obtain a residual conductive film layer 62 (i.e., the test pad 2 and the bonding pad 3), as shown in FIG. 11.

In some embodiments, if the bonding pad 3 and the test pad 2 are connected by a conductive connection structure, and the material of the conductive connection structure is the same as that of the bonding pad 3 and the test pad 2, the conductive connection structure may be prepared simultaneously with the bonding pad 3 and the test pad 2. As shown in FIGS. 9, 10, and 11, in step S330 of the fabrication process, an appropriate mask may be selected such that the pattern of the conductive connection structure between the test pad 2 and the bonding pad 3 may be transferred onto the photoresist layer, along with the pattern of the test pad 2 and the bonding pad 3. Thus, in step S340, the formed photoresist protective layer 63 may have a pattern of the test pad 2, the bonding pad 3, and the conductive connection structure. In step S360, the remaining conductive film layer 62 may include the test pad 2, the bonding pad 3 and the conductive connection structure.

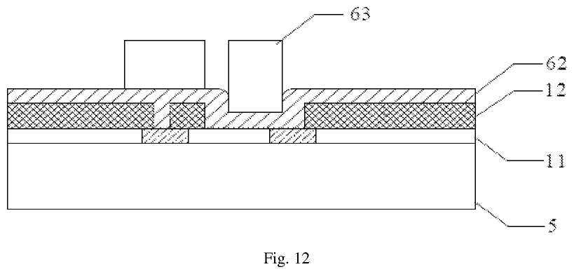

If the bonding pad 3 and the test pad 2 are isolated from each other, a suitable mask may be selected in step S330, so that the photoresist protective layer 63 in step S340 may have a pattern as shown in FIG. 12, with the isolation region between the bonding pad 3 and the test pad 2 exposed.

It should be noted that, although the various steps of the method of the present invention are described in a particular order in the drawings, this does not require or imply that the steps must be performed in that particular order, or that all illustrated five steps must be performed to achieve the desired result. Additionally, or alternatively, some steps may be omitted, multiple steps may be combined into one step, and/or one step may be decomposed into multiple steps, etc., all of which are considered part of this present invention.

The present invention further provides a semiconductor device including any of the pad structures described in the above-described pad structure embodiments. The semiconductor device may be a memory, a processor, or other semiconductor integrated circuit device.

The pad structure employed in the semiconductor device of the embodiment of the present invention may be the same as the pad structure in the embodiment of the pad structure described above, and therefore may have the same advantageous effects, which will not be repeatedly described herein for the sake of conciseness.

It should be understood that the present invention does not limit its application to the detailed structure and arrangement of the components presented in the specification. The present invention is capable of other embodiments and of various embodiments. The foregoing variations and modifications are intended to fall within the scope of the present invention. It is to be understood that the present invention disclosed and claimed herein extends to all alternative combinations of two or more individual features that are mentioned or apparent in the drawings. All of these different combinations constitute a number of alternative aspects of the present invention. The embodiments described in the specification are illustrative of the best mode of the present invention and will enable those skilled in the art to utilize this present invention.

1. A pad structure, comprising:
a substrate;
a first dielectric layer disposed on the substrate;
a groove disposed in the first dielectric layer; and
a bonding pad and a test pad, wherein one of the bonding pad and the test pad is disposed outside the groove and on a surface of the first dielectric layer not adjacent to the substrate, and the other one of the bonding pad and the test pad is disposed on a bottom of the groove.

2. The pad structure of claim 1, wherein the bonding pad is disposed outside of the groove and on the surface of the first dielectric layer not adjacent to the substrate, and the test pad is disposed on the bottom of the groove.

3. The pad structure of claim 1, wherein the groove has a depth in a range of 100 nm to 1 μm.

4. The pad structure of claim 2, wherein the substrate comprises a wiring layer, the wiring layer comprising:
a test wiring connected to the test pad.

5. The pad structure of claim 4, wherein the test wiring is exposed by the groove and the test pad is coupled to an exposed surface of the test wiring.

6. The pad structure of claim 1, wherein the wiring layer further comprises:
a solder wiring coupled to the bonding pad.

7. The pad structure of claim 6, wherein the solder wiring is coupled to the bonding pad via a conductive pillar passing through the first dielectric layer.

8. The pad structure of claim 1, wherein the test pad and the bonding pad are isolated from each other.

9. The pad structure of claim 1, wherein the test pad and the bonding pad are coupled to each other via a conductive connection structure.

10. The pad structure of claim 1, wherein a distance between a surface of the test pad facing away from the substrate and the substrate is 100 nm to 1 μm shorter than a distance between a surface of the bonding pad facing away from the substrate and the substrate.

11. The pad structure of claim 1, wherein the test pad and the bonding pad are made of a same material.

12. The pad structure of claim 1, wherein the test pad has a thickness same as a thickness of the bonding pad.

13. The pad structure of claim 1, wherein the pad structure further comprises:
a protective layer disposed on a side of the first dielectric layer not adjacent to the substrate and exposing the test pad and the bonding pad.

14. A method of fabricating a pad structure, comprising:
providing a substrate;
forming a first dielectric layer on the substrate;
forming a groove in the first dielectric layer; and
forming a bonding pad and a test pad, wherein one of the bonding pad and the test pad is disposed outside the groove and on a surface of the first dielectric layer not adjacent to the substrate, and the other one of the bonding pad and the test pad is disposed on a bottom of the groove.

15. The method of fabricating a pad structure of claim 14, wherein forming a groove in the first dielectric layer comprises:
forming a photoresist layer on the surface of the first dielectric layer not adjacent to the substrate;
exposing the photoresist layer with respect to a mask to transfer a pattern of the mask to the photoresist layer;
developing the photoresist layer to expose a groove area for forming the groove;
etching the groove area to form the groove; and
removing the photoresist layer.

16. The method of fabricating a pad structure of claim 14, wherein forming the bonding pad and the test pad comprises:
forming a conductive film layer covering the bottom of the groove and the surface of the first dielectric layer not adjacent to the substrate;
forming a photoresist protection layer on a surface of the conductive film layer facing away from the substrate, the photoresist protection layer having a pattern of the bonding pad and the test pad exposing a portion of the conductive film layer;
removing the exposed portion of the conductive film layer by etching; and
removing the photoresist protective layer.

17. The method of fabricating a pad structure of claim 16, wherein forming a photoresist protective layer on the surface of the conductive film layer facing away from the substrate comprises:
forming a photoresist layer on the surface of the conductive film layer facing away from the substrate;
exposing the photoresist layer with respect to a mask to transfer a pattern of the mask to the photoresist layer; and
developing the photoresist layer so that the photoresist layer only covers areas where the bonding pad and the test pad are to be formed.

18. The method of fabricating a pad structure of claim 16, wherein the bonding pad and the test pad are coupled to each other via a conductive connection structure, and forming a photoresist protection layer on a surface of the conductive film layer facing away from the substrate comprising:
forming a photoresist layer on the surface of the conductive film layer facing away from the substrate;
exposing the photoresist layer with respect to a mask to transfer a pattern of the mask to the photoresist layer; and
developing the photoresist layer so that the photoresist layer only covers areas where the bonding pad, the test pad, and the conductive connection structure are to be formed.

19. A semiconductor device comprising a pad structure, the pad structure comprising:
a substrate;
a first dielectric layer disposed on the substrate;
a groove disposed in the first dielectric layer; and
a bonding pad and a test pad, wherein one of the bonding pad and the test pad is disposed outside the groove and on a surface of the first dielectric layer not adjacent to the substrate, and the other one of the bonding pad and the test pad is disposed on a bottom of the groove.

20. The semiconductor device of claim 19, wherein the bonding pad is disposed outside the groove and on the surface of the first dielectric layer not adjacent to the substrate, and the test pad is disposed on the bottom of the groove.
